(19) United States
(12) Patent Application Publication
(10) Pub. No.: US 2025/0087585 A1
(43) Pub. Date: Mar. 13, 2025

(54) SEMICONDUCTOR DEVICE AND DATA STORAGE SYSTEM

(71) Applicant: SAMSUNG ELECTRONICS CO., LTD., Suwon-si (KR)

(72) Inventors: Youngjin Jung, Suwon-si (KR); Jaehwang Sim, Suwon-si (KR)

(21) Appl. No.: 18/731,176

(22) Filed: May 31, 2024

(30) Foreign Application Priority Data
Sep. 11, 2023 (KR) 10-2023-0120633

(51) Int. Cl. H01L 23/528; H01L 25/065; H10B 43/10; H10B 43/27; H10B 43/35; H10B 43/40; H10B 80/00

(52) U.S. Cl. CPC H01L 23/5283; H01L 23/528; H01L 25/0657; H10B 43/10; H10B 43/27; H10B 43/35; H10B 43/40; H10B 80/00; H01L 2225/06506

(57) ABSTRACT

A semiconductor device includes a first word line having a first electrode portion and a first extension portion extending from the first electrode portion, a second word line having a second electrode portion disposed at a higher level than the first electrode portion and a second extension portion extending from the second electrode portion, a first vertical memory structure penetrating through the first and second electrode portions in a vertical direction, and a first interconnection structure electrically connected to the first extension portion. The first extension portion includes a first lower portion extending from the first electrode portion and a first plug portion extending upwardly from at least one side of the first lower portion and connected to the first interconnection structure. At least a portion of the first lower portion has a thickness greater than a thickness of the first electrode portion.

### CROSS-REFERENCE TO RELATED APPLICATION

This application claims the benefit under 35 USC 119 (a) of Korean Patent Application No. 10-2023-0120633, filed on Sep. 11, 2023, in the Korean Intellectual Property Office, the entire disclosure of which is incorporated herein by reference.

### TECHNICAL FIELD

The present disclosure relates to semiconductor devices and data storage systems including gate electrodes.

### BACKGROUND

In electronic systems requiring data storage, semiconductor devices capable of storing high-capacity data are required. Accordingly, methods of increasing the data storage capacity of semiconductor devices are being studied. For example, as a method for increasing the data storage capacity of a semiconductor device, a semiconductor device including memory cells arranged three-dimensionally rather than memory cells arranged two-dimensionally has been proposed.

### SUMMARY

Aspects of this disclosure provide semiconductor devices in which integration may be increased, and data storage systems including the semiconductor devices.

A semiconductor device according to some implementations is provided. The semiconductor device includes a first word line having a first electrode portion and a first extension portion extending from the first electrode portion; a second word line having a second electrode portion disposed on a level higher than a level of the first electrode portion and a second extension portion extending from the second electrode portion; a first vertical memory structure penetrating through the first and second electrode portions in a vertical direction; and a first interconnection structure electrically connected to the first extension portion. The first extension portion includes a first lower portion extending from the first electrode portion and a first plug portion extending upwardly from at least one side of the first lower portion and connected to the first interconnection structure. At least a portion of the first lower portion has a thickness greater than a thickness of the first electrode portion.

A semiconductor device according to some implementations is provided. The semiconductor device includes a first memory cell array area and a connection area adjacent to the first memory cell array area; separation structures crossing the first memory cell array area and the connection area; word lines disposed between the separation structures and within the first memory cell array area and the connection area; a first vertical memory structure within the first memory cell array area, penetrating through the word lines and including a first data storage structure; vertical support structures within the connection area; and a first insulating pattern. The word lines include a first word line and a second word line, the first word line includes a first electrode portion and a first extension portion extending from the first electrode portion, and the second word line includes a second electrode portion disposed on a level higher than a level of the first electrode portion and a second extension portion extending from the second electrode portion. The first extension portion includes a first lower portion disposed below the first insulating pattern and a first plug portion extending from the first lower portion and disposed on a side surface of the first insulating pattern. An upper end of the first plug portion is disposed on a level higher than that of an uppermost word line among the word lines. The first insulating pattern penetrates through the second electrode portion of the second word line. The vertical support structures include a first vertical support structure penetrating through the first and second electrode portions; and a second vertical support structure disposed below the first insulating pattern. The first lower portion includes a first thickness portion disposed below the first insulating pattern and not vertically overlapping the vertical support structures; and a second thickness portion disposed between the second vertical support structure and the first insulating pattern.

A data storage system according to some implementations is provided. The data storage system includes a semiconductor device including an input/output pad; and a controller electrically connected to the semiconductor device through the input/output pad and controlling the semiconductor device. The semiconductor device includes a first word line having a first electrode portion and a first extension portion extending from the first electrode portion; a second word line having a second electrode portion disposed on a level higher than a level of the first electrode portion and a second extension portion extending from the second electrode portion; a first vertical memory structure penetrating through the first and second electrode portions in a vertical direction; and a first interconnection structure electrically connected to the first extension portion. The first extension portion includes a first lower portion extending from the first electrode portion and a first plug portion extending upwardly from at least one side of the first lower portion and connected to the first interconnection structure. At least a portion of the first lower portion has a thickness greater than a thickness of the first electrode portion.

### BRIEF DESCRIPTION OF DRAWINGS

The above and other aspects, features, and advantages of implementations according to this disclosure will be more clearly understood from the following detailed description, taken in conjunction with the accompanying drawings, in which:

FIGS. 1, 2A, 2B, 2C, 3, 4A, 4B, 4C, 5, and 6 are diagrams illustrating a semiconductor device according to some implementations;

FIG. 7 is a partial enlarged view illustrating a modified example of a semiconductor device according to some implementations;

FIG. 8 is a partial enlarged view illustrating a modified example of a semiconductor device according to some implementations;

FIG. 9 is a partially enlarged cross-sectional view illustrating a modified example of a semiconductor device according to some implementations;

FIG. 10 is a partially enlarged cross-sectional view illustrating a modified example of a semiconductor device according to some implementations;

FIG. 11 is a partial top view illustrating a modified example of a semiconductor device according to some implementations;

FIG. 12 is a cross-sectional view illustrating a modified example of a semiconductor device according to some implementations;

FIG. 13 is a cross-sectional view illustrating a modified example of a semiconductor device according to some implementations;

FIGS. 14A and 14B are diagrams illustrating a modified example of a semiconductor device according to some implementations;

FIGS. 15A, 15B, and 15C are diagrams illustrating a modified example of a semiconductor device according to some implementations;

FIG. 16 is a process flow diagram illustrating an example of a semiconductor device manufacturing method according to some implementations;

FIG. 17 is a process flow diagram illustrating another example of a semiconductor device manufacturing method according to some implementations;

FIG. 18 is a diagram schematically illustrating a data storage system including a semiconductor device according to some implementations; and

FIG. 19 is a perspective view schematically illustrating a data storage system including a semiconductor device according to some implementations.

### DETAILED DESCRIPTION

Hereinafter, terms such as “upper”, “intermediate, “middle”, “lower” and the like may be replaced with other terms, such as “first”, “second”, “third” and the like to describe the elements of the specification. Terms such as “first”, “second” and “third” may be used to describe various elements, but the elements are not limited by the terms, and a “first component” may be referred to as a “second component.”

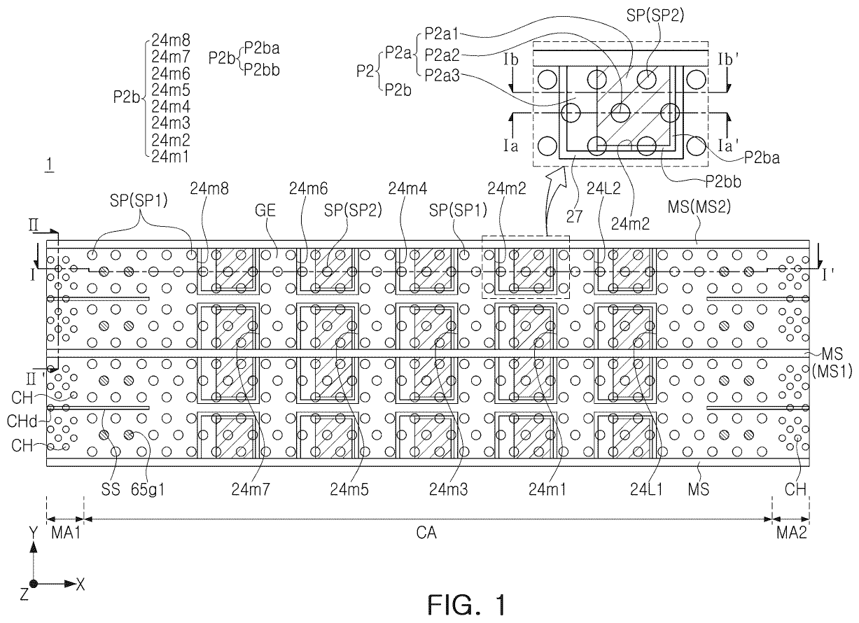

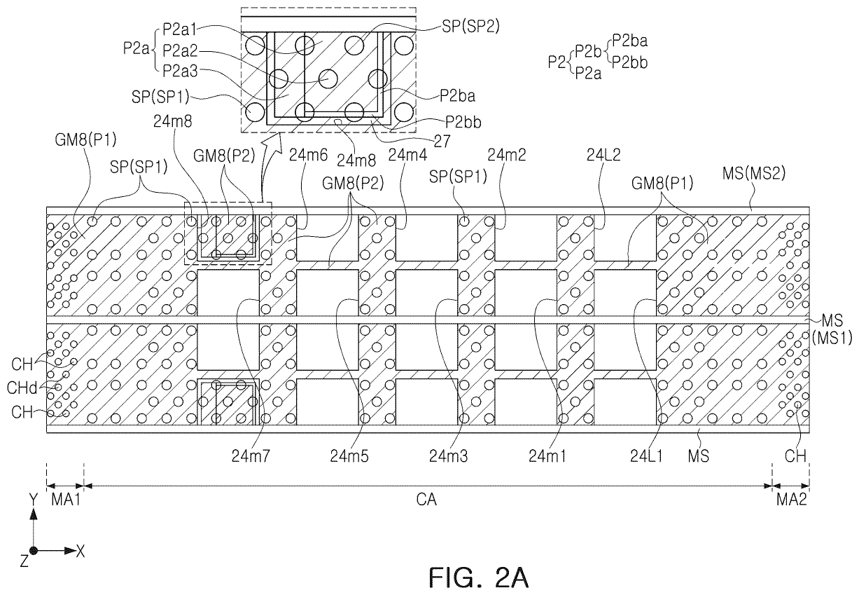

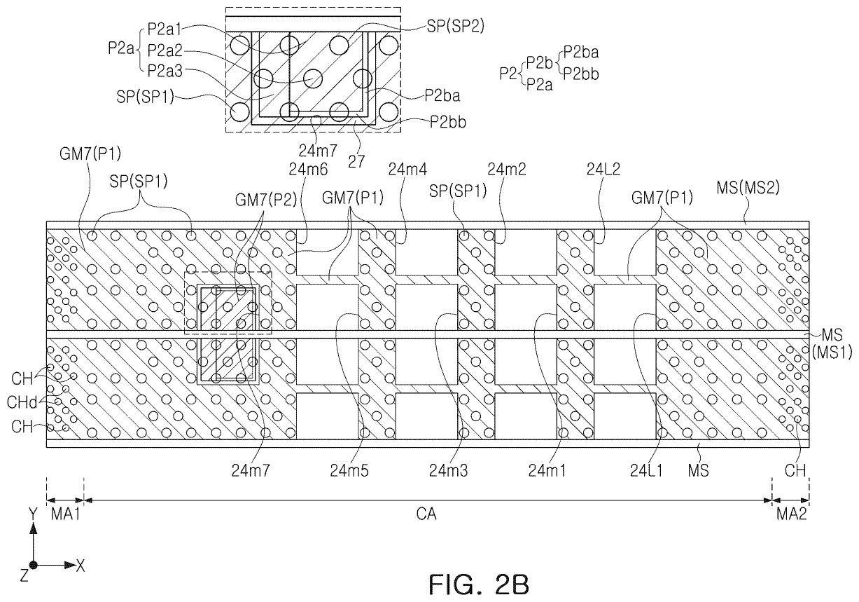

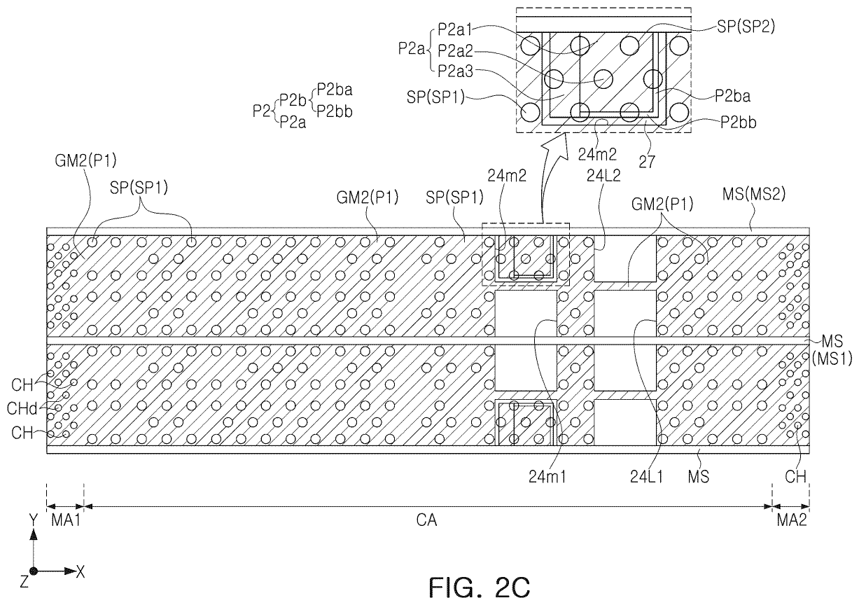

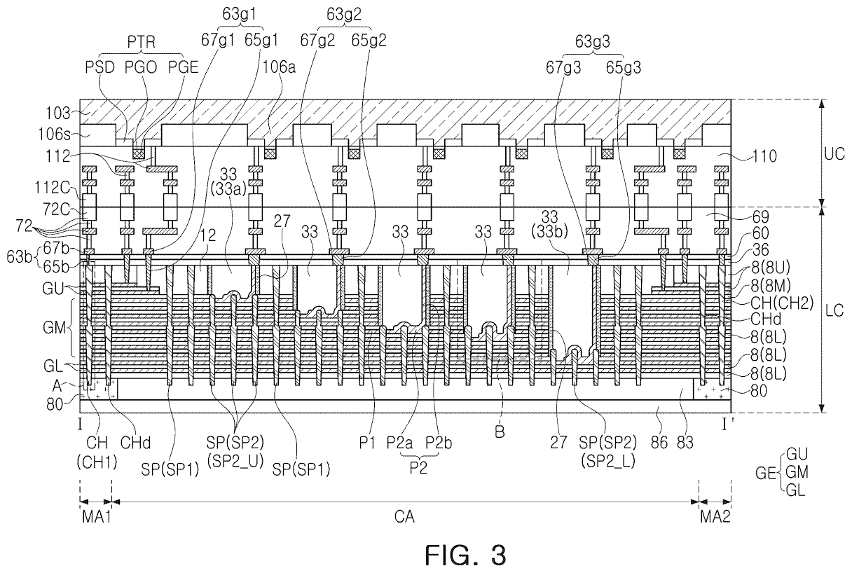

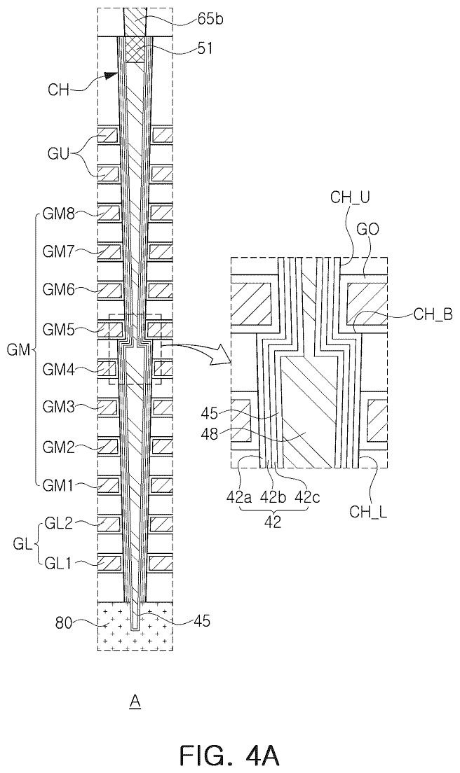

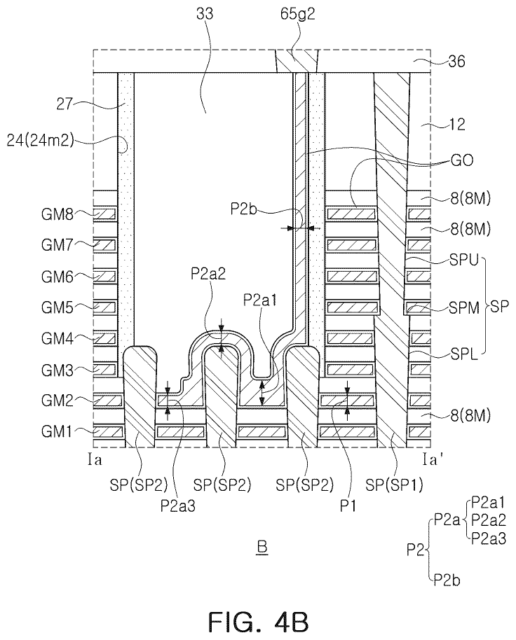

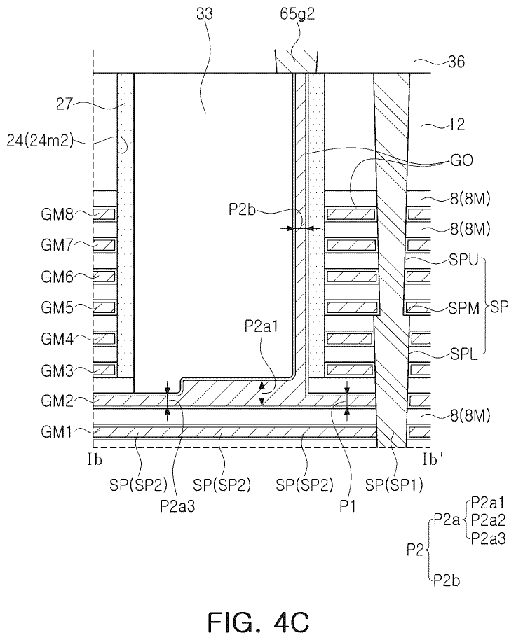

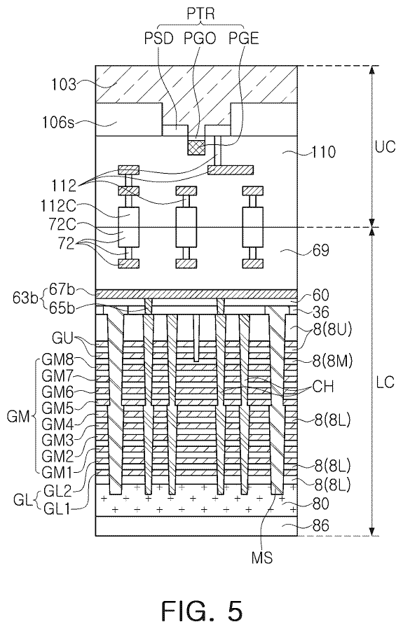

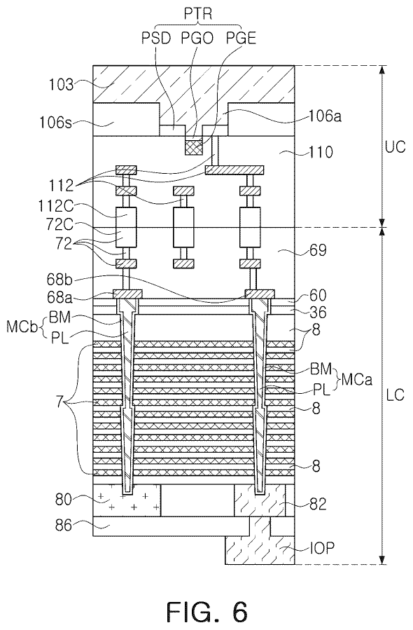

First, with reference to FIGS. 1 to 6, a semiconductor device according to some implementations will be described. FIGS. 1, 2A, 2B, 2C, 3A, 3B, 3C, 4, 5, and 6 are diagrams illustrating the semiconductor device. FIG. 1 is a top view illustrating the semiconductor device, and FIGS. 2A to 2C are top views illustrating the planar shape of word lines in the semiconductor device. FIG. 3A is a cross-sectional view illustrating the area taken along line II′ of FIG. 1, and FIG. 3B is a partial enlarged view illustrating the area marked ‘A’ in FIG. 3A and illustrates the area taken along the line ‘Ia-Ia’ in FIG. 1. FIG. 3C is a partially enlarged view illustrating the area taken along line II-II′ of FIG. 1 at the same height level as the partially enlarged view of FIG. 3b. FIG. 4 is a cross-sectional view illustrating the area taken along line III-III′ in FIG. 1, FIG. 5 is a partial enlarged view illustrating the area marked ‘B’ in FIG. 4, and FIG. 6 is a cross-sectional view illustrating an area disposed outside the memory cell array areas and the connection area in the semiconductor device.

Referring to FIGS. 1 to 6, a semiconductor device 1 according to some implementations may include a lower chip structure LC and an upper chip structure UC vertically overlapping the lower chip structure LC (e.g., overlapping the lower chip structure LC along a vertical direction). The upper chip structure UC may be disposed on the lower chip structure LC.

The lower chip structure LC may include a first memory cell array area MA1 and a connection area CA adjacent to the first memory cell array area MA1.

The lower chip structure LC may further include a second memory cell array area MA2. The first memory cell array area MA1, the connection area CA, and the second memory cell array area MA2 may be sequentially arranged in the X-direction.

The lower chip structure LC may include the second memory cell array area MA2, but the scope of this disclosure is not limited thereto. For example, in some implementations, the second memory cell array area MA2 may be omitted.

The lower chip structure LC may include a plurality of gate electrodes GE spaced apart from each other. Each of the plurality of gate electrodes GE may be formed of W, Ru, Mo, Nb, Ni, Co, Ti, Ta, TiN, TaN, WN, NbN, TiAl, TiAlN, TiSi, TiSiN, TaSi, TaSiN, RuTiN, NiSi, CoSi, or combinations thereof. However, the present inventive concept is not limited thereto. For example, each of the plurality of gate electrodes GE may include a single layer or multiple layers of the above-described materials.

The plurality of gate electrodes GE may include one or a plurality of lower gate electrodes GL, a plurality of intermediate gate electrodes GM disposed on the one or a plurality of lower gate electrodes GL, and one or more upper gate electrodes GU disposed on the plurality of intermediate gate electrodes GM.

As shown in FIG. 4A, the one or a plurality of lower gate electrodes GL may include a first lower gate electrode GL1 and a second lower gate electrode GL2 on the first lower gate electrode GL1.

The plurality of intermediate gate electrodes GM may include a plurality of word lines. Accordingly, the plurality of intermediate gate electrodes (GM) may also be referred to as word lines.

The plurality of intermediate gate electrodes (GM) may include a first intermediate gate electrode (GM1), a second intermediate gate electrode (GM2) on the first intermediate gate electrode (GM1), a third intermediate gate electrode (GM3) on the second intermediate gate electrode (GM2), a fourth intermediate gate electrode (GM4) on the third intermediate gate electrode (GM3), a fifth intermediate gate electrode (GM5) on the fourth intermediate gate electrode (GM4), a sixth intermediate gate electrode (GM6) on the fifth intermediate gate electrode (GM5), a seventh intermediate gate electrode (GM7) on the sixth intermediate gate electrode (GM6), and an eighth intermediate gate electrode (GM8) on the seventh intermediate gate electrode (GM7).

The one or a plurality of upper gate electrodes GU may include a first upper gate electrode and a second upper gate electrode on the first upper gate electrode.

The number of the plurality of gate electrodes GE illustrated in the drawings is an example, and the number of the plurality of gate electrodes GE may be different from the illustrated number in various implementations.

The one or a plurality of lower gate electrodes GL and the plurality of intermediate gate electrodes GM may be disposed in the first memory cell array area MA1, the connection area CA, and the second memory cell array area MA2. Each of the one or a plurality of lower gate electrodes GL and the plurality of intermediate gate electrodes GM may extend continuously from within the first memory cell array area MA1 to the second memory cell array area MA2.

The one or a plurality of upper gate electrodes GU may be at the same height level and spaced apart from each other with the connection area CA interposed therebetween. For example, one of the one or a plurality of upper gate electrodes GU may extend from the first memory cell array area MA1 to the connection area CA adjacent to the first memory cell array area MA1 and may be spaced apart from the second memory cell array area MA2, and another upper gate electrode of the one or a plurality of upper gate electrodes GU may extend from the second memory cell array area MA2 to the connection area CA adjacent to the second memory cell array area MA2 and may be spaced apart from the first memory cell array area MA1.

The lower chip structure LC may further include an upper separation pattern SS penetrating through the one or a plurality of upper gate electrodes GU disposed on a level higher than that of the plurality of intermediate gate electrodes GM.

Each of the one or a plurality of lower gate electrodes GL and the plurality of intermediate gate electrodes GM may include an electrode portion P1 and an extension portion P2 extending from the electrode portion P1. In each of the one or a plurality of lower gate electrodes GL and the plurality of intermediate gate electrodes GM, the electrode portion P1 and the extension portion P2 may be formed integrally.

In each of the one or a plurality of lower gate electrodes GL and the plurality of intermediate gate electrodes GM, the electrode portion P1 may be disposed in the first memory cell array area MA1, the connection area CA, and the second memory cell array area MA2, and the extension portion P2 may be disposed within the connection area CA.

The electrode portions P1 of the one or a plurality of lower gate electrodes GL and the plurality of intermediate gate electrodes GM may be stacked while being spaced apart from each other in the Z-direction.

In some implementations, the Z-direction may be referred to as the vertical direction.

In each of the one or a plurality of lower gate electrodes GL and the plurality of intermediate gate electrodes GM, the extension portion P2 may include a lower portion P2a extending from the electrode part P1 and a plug portion P2b extending upwardly from at least one side of the lower portion P2a.

The plug portions P2b of the one or a plurality of lower gate electrodes GL and the plurality of intermediate gate electrodes GM may have upper surfaces positioned on the same level as each other.

Upper ends of the plug portions P2b may be disposed on a level higher than that of the uppermost intermediate gate electrode (GM8) among the plurality of intermediate gate electrodes GM.

The upper ends of the plug portions P2b may be disposed on a level higher than that of the one or upper gate electrodes GU.

The lower chip structure LC may further include interlayer insulating layers 8 and a capping insulating layer 12. The interlayer insulating layers 8 may include lower interlayer insulating layers 8L alternately stacked with the electrode portions P1 and upper interlayer insulating layers 8U alternately stacked with the one or a plurality of upper gate electrodes GU. Among the electrode portions P1 and the lower interlayer insulating layers 8L, the uppermost layer and the lowermost layer may be the lower interlayer insulating layer.

The lower chip structure LC may further include connection openings 24 disposed on the extension portions P2 of the one or a plurality of lower gate electrodes GL and the plurality of intermediate gate electrodes GM, and insulating patterns 33 in the connection openings 24.

The lower chip structure LC may further include a dielectric layer GO covering the top, side, and lower surfaces of each of the plurality of gate electrodes GE.

The lower chip structure LC may further include insulating spacers 27 on the sidewalls of the connection openings 24.

The connection openings 24 may include a first lower connection opening 24L1, a second lower connection opening 24L2, a first intermediate connection opening 24m1, a second intermediate connection opening 24m2, a third intermediate connection opening 24m3, a fourth intermediate connection opening 24m4, a fifth intermediate connection opening 24m5, a sixth intermediate connection opening 24m6, a seventh intermediate connection opening 24m7, and an eighth intermediate connection opening 24m8.

In the extension portion P2 of the first lower gate electrode GL1, the lower portion (P2a) may be disposed below the insulating pattern 33 disposed in the first lower connection opening 24L1, and the plug portion (P2b) may be disposed between the insulating pattern 33 disposed in the first lower connection opening 24L1 and the insulating spacer 27 disposed in the first lower connection opening 24L1. The first lower connection opening 24L1 and the insulating pattern 33 disposed in the first lower connection opening 24L1 may penetrate through the second lower gate electrode GL2 and the plurality of intermediate gate electrodes GM, which are disposed on a level higher than that of the first lower gate electrode GL1.

In the extension portion P2 of the second lower gate electrode GL2, the lower portion (P2a) may be disposed below the insulating pattern 33 disposed in the second lower connection opening 24L2, and the plug portion (P2b) may be disposed between the insulating pattern 33 disposed in the second lower connection opening 24L2 and the insulating spacer 27 disposed in the second lower connection opening 24L2. The second lower connection opening 24L2 and the insulating pattern 33 disposed in the second lower connection opening 24L2 may penetrate through the plurality of intermediate gate electrodes GM disposed on a level higher than that of the second lower gate electrode GL2.

In the extension portion P2 of the first intermediate gate electrode GM1, the lower portion P2a may be disposed below the insulating pattern 33 disposed in the first intermediate connection opening 24m1, and the plug portion (P2b) may be disposed between the insulating pattern 33 disposed in the first intermediate connection opening 24m1 and the insulating spacer 27 disposed in the first intermediate connection opening 24m1.

The first intermediate connection opening 24m1 and the insulating pattern 33 disposed in the first intermediate connection opening 24m1 may penetrate through the second to eighth intermediate gate electrodes (GM2 to GM8) disposed on a level higher than that of the first intermediate gate electrode (GM1).

In the extension portion P2 of the second intermediate gate electrode Gm2, the lower portion P2a may be disposed below the insulating pattern 33 disposed in the second intermediate connection opening 24m2, and the plug portion (P2b) may be disposed between the insulating pattern 33 disposed in the second intermediate connection opening 24m2 and the insulating spacer 27 disposed in the second intermediate connection opening 24m2.

The second intermediate connection opening 24m2 and the insulating pattern 33 disposed in the second intermediate connection opening 24m2 may penetrate through the third to eighth intermediate gate electrodes (GM3 to GM8) disposed on a level higher than that of the second intermediate gate electrode (GM2).

In the extension portion P2 of the third intermediate gate electrode Gm3, the lower portion (P2a) may be disposed below the insulating pattern 33 disposed in the third intermediate connection opening 24m3, and the plug portion (P2b) may be disposed between the insulating pattern 33 disposed in the third intermediate connection opening 24m3 and the insulating spacer 27 disposed in the third intermediate connection opening 24m3.

The third intermediate connection opening 24m3 and the insulating pattern 33 disposed in the third intermediate connection opening 24m3 may penetrate through the fourth to eighth intermediate gate electrodes (GM4 to GM8) disposed on a level higher than that of the third intermediate gate electrode (GM3).

In the extension portion P2 of the fourth intermediate gate electrode Gm4, the lower portion P2a may be disposed below the insulating pattern 33 disposed in the fourth intermediate connection opening 24m4, and the plug portion (P2b) may be disposed between the insulating pattern 33 disposed in the fourth intermediate connection opening 24m4 and the insulating spacer 27 disposed in the fourth intermediate connection opening 24m4.

The insulating pattern 33 disposed in the fourth intermediate connection opening 24m4 and the fifth intermediate connection opening 24m5 may penetrate through the fifth to eighth intermediate gate electrodes (GM5 to GM8) disposed on a level higher than that of the fourth intermediate gate electrode (GM4).

In the extension portion P2 of the fifth intermediate gate electrode Gm5, the lower portion P2a may be disposed below the insulating pattern 33 disposed in the fifth intermediate connection opening 24m5, and the plug portion (P2b) may be disposed between the insulating pattern 33 disposed in the fifth intermediate connection opening 24m5 and the insulating spacer 27 disposed in the fifth intermediate connection opening 24m5.

The fifth intermediate connection opening 24m5 and the insulating pattern 33 disposed in the fifth intermediate connection opening 24m5 may penetrate through the sixth to eighth intermediate gate electrodes (GM6 to GM8) disposed on a level higher than that of the fifth intermediate gate electrode (GM5).

In the extension portion P2 of the sixth intermediate gate electrode Gm6, the lower portion P2a may be disposed below the insulating pattern 33 disposed in the sixth intermediate connection opening 24m6, and the plug portion (P2b) may be disposed between the insulating pattern 33 disposed in the sixth intermediate connection opening 24m6 and the insulating spacer 27 disposed in the sixth intermediate connection opening 24m6.

The sixth intermediate connection opening 24m6 and the insulating pattern 33 disposed in the sixth intermediate connection opening 24m6 may penetrate through the seventh and eighth intermediate gate electrodes (GM7, GM8) disposed on a level higher than that of the sixth intermediate gate electrode (GM6).

In the extension portion P2 of the seventh intermediate gate electrode Gm7, the lower portion P2a may be disposed below the insulating pattern 33 disposed in the seventh intermediate connection opening 24m7, and the plug portion (P2b) may be disposed between the insulating pattern 33 disposed in the seventh intermediate connection opening 24m7 and the insulating spacer 27 disposed in the seventh intermediate connection opening 24m7.

The seventh intermediate connection opening 24m7 and the insulating pattern 33 disposed in the seventh intermediate connection opening 24m7 may penetrate through the eighth intermediate gate electrode (GM8) disposed on a level higher than that of the seventh intermediate gate electrode (GM7).

In the extension portion P2 of the eighth intermediate gate electrode Gm8, the lower portion P2a may be disposed below the insulating pattern 33 disposed in the eighth intermediate connection opening 24m8, and the plug portion (P2b) may be disposed between the insulating pattern 33 disposed in the eighth intermediate connection opening 24m8 and the insulating spacer 27 disposed in the eighth intermediate connection opening 24m8.

The insulating patterns 33 may have lower surfaces of different heights and upper surfaces of substantially the same height. Top surfaces of the insulating patterns 33 may be disposed on a level higher than that of the uppermost gate GU among the gates GE.

The insulating spacers 27 may have upper surfaces of substantially the same height. The upper surfaces of the insulating spacers 27 may be coplanar with the upper surfaces of the insulating patterns 33.

The plug portions P2a may have upper surfaces of substantially the same height. The upper surfaces of the plug portions P2a may be coplanar with the upper surfaces of the insulating spacers 27 and the insulating patterns 33.

The lower chip structure LC may further include vertical memory structures CH and vertical dummy memory structures CHd disposed in the first and second memory cell array areas MA1 and MA2. The vertical memory structures CH and the vertical dummy memory structures CHd may penetrate through the electrode portions P1, the upper gate electrodes GU, and the interlayer insulating layers 8. The vertical memory structures (CH) may include first vertical memory structures CH1 disposed in the first memory cell array area MA1 and second vertical memory structures CH2 disposed in the second memory cell array area MA2.

Each of the vertical memory structures CH may include an insulating core region 48, a channel layer 45 on the outer side of the insulating core region 48, a data storage structure 42 on the outer side surface of the channel layer 45, and a pad layer 51 disposed on the insulating core region 48 and in contact with the channel layer 45.

The channel layer 45 may include a semiconductor material such as silicon. The pad layer 51 may include at least one of doped polysilicon, metal nitride (e.g., TiN, or the like), metal (e.g., W, or the like), and a metal-semiconductor compound (e.g., TiSi, or the like). The data storage structure 42 may include a first dielectric layer 42a, a second dielectric layer 42c, and a data storage layer 42b between the first dielectric layer 42a and the second dielectric layer 42c. The first dielectric layer 42a may include at least one of silicon oxide and a high dielectric material. The second dielectric layer 42c may include silicon oxide or silicon oxide doped with impurities. The second dielectric layer 42c may be in contact with the channel layer 45.

The data storage layer 42b may include a material capable of storing information by trapping a charge, for example, silicon nitride. The data storage layer 42b may include areas that may store information in a semiconductor device such as a flash memory device.

In some implementations, the data storage structure 42 includes the data storage layer 42b capable of storing information by trapping a charge, but the scope of this disclosure is not limited thereto. For example, the data storage structure 42 may be a data storage structure used in a ferroelectric memory that may store information using remnant polarization by dipoles.

Each of the vertical memory structures CH may include a lower vertical part CH_L, an upper vertical part CH_U on the lower vertical part CH_L, and a joint portion CH_B between the lower vertical part CH_L and the upper vertical part CH_U.

In the vertical memory structures CH, the joint portions CH_B may be disposed between the plurality of intermediate gates GM. For example, the joint portions CH_B may be disposed between the fourth intermediate gate electrode GM4 and the fifth intermediate gate electrode GM5 among the plurality of intermediate gates GM.

In each of the vertical memory structures CH, the joint portion CH_B may have a side surface that is curved from the side surface of the lower vertical portion CH_L and the side surface of the upper vertical portion CH_U.

The vertical dummy memory structures CHd may have the same cross-sectional structure as the vertical memory structures CH, and may include the same material layers as the material layers of the vertical memory structures CH. For example, each of the vertical dummy memory structures CHd may include the channel layer 45, the data storage structure 42, the insulating core region 48, and the pad layer 51. The vertical dummy memory structures CHd may be electrically isolated.

The vertical dummy memory structures CHd may include vertical dummy memory structures in contact with the upper separation pattern SS and vertical dummy memory structures adjacent to the connection area CA.

The lower chip structure LC may further include a plurality of vertical support structures SP disposed in the connection area CA.

The plurality of vertical support structures SP may include first vertical support structures SP1 penetrating through the electrode portions P1, the interlayer insulating layers 8, and the capping insulating layer 12, and second vertical support structures SP2 disposed below the insulating patterns 33. The plurality of vertical support structures SP may have lower surfaces arranged at substantially the same level. The plurality of vertical support structures SP may prevent deformation of the gate electrodes GE.

Each of the plurality of vertical support structures SP may be an insulating pillar that continuously extends from the lower surface to the upper surface. The plurality of vertical support structures SP may not include a material of the channel layer 45 of the vertical memory structures CH.

In the extension portions P2 of the one or a plurality of lower gate electrodes GL and the plurality of intermediate gate electrodes GM, the lower portions P2a may be disposed between the insulating patterns 33 and the second vertical support structures SP2.

Each of the first vertical support structures SP1 may include a lower vertical portion SPL, a upper vertical portion SPU on the lower vertical portion SPL, and a joint portion SPM between the lower vertical portion SPL and the upper vertical portion SPU.

The joint portions SPM of the first vertical support structures SP1 may be disposed at substantially the same level as the joint portions CH_B of the vertical memory structures CH. The side shape of the joint portions SPM of the first vertical support structures SP1 may be substantially the same as the side shape of the joint portions CH_B of the vertical memory structures CH.

Each of the lower portions P2a of the extension portions P2 of the one or a plurality of lower gate electrodes GL and the plurality of intermediate gate electrodes GM may include a first thickness portion P2al, a second thickness portion P2a2, and a third thickness portion P2a3.

The following description refers to the examples of the first thickness portion P2al, the second thickness portion P2a2, the third thickness portion P2a3, and the second vertical support structures SP2 illustrated in FIGS. 4B and 4C, in which thicknesses are illustrated by pairs of arrows.

At least a portion of the lower portion P2a may have a thickness greater than that of the first electrode portion P1. For example, in the lower portion P2a, the first thickness portion P2al does not vertically overlap the second vertical support structures SP2, and may be a portion having a first thickness greater than the thickness of the first electrode part P1. The first thickness of the first thickness portion P2al may be greater than the thickness of the plug portion P2b. The first thickness of the first thickness portion P2al may be substantially equal to the sum of the thickness of the plug portion P2b and the thickness of the electrode portion P1.

In the lower portion P2a, the second thickness portion (P2a2) may be a portion that covers the upper surface of the second vertical support structures SP2 and has a second thickness smaller than the first thickness of the first thickness part P2al. The second thickness of the second thickness portion P2a2 may be substantially the same as the thickness of the plug portion P2b. The second thickness portion P2a2 may have a convex upper surface.

In the lower portion P2a, the third thickness portion P2a3 may be a portion that does not vertically overlap the second vertical support structures SP2 and has a third thickness smaller than the first thickness. The third thickness of the third thickness portion P2a3 may be substantially the same as the thickness of the electrode portion P1.

The vertical support structure SP2 disposed below the insulating pattern 33 on the second intermediate gate electrode GM2 as illustrated in FIG. 4B may penetrate through the gate electrodes GL1, GL2, GM1 disposed below the second intermediate gate electrode GM2, and the second intermediate gate electrode GM2 may be disposed on a level higher than that of the upper surface of the electrode portion P1.

In the vertical support structure SP2 of FIG. 4B, the height of the second intermediate gate electrode GM2 protruding upward from the upper surface of the electrode portion P1 may be greater than the thickness of the electrode portion P1.

In the vertical support structure SP2 of FIG. 4B, the height of the second intermediate gate electrode GM2 protruding upward from the upper surface of the electrode portion P1 may be greater than twice the thickness of the electrode portion P1.

In the vertical support structure SP2 of FIG. 4B, the upper surface of the vertical support structure SP2 may be disposed at a level higher than that of the upper surface of the electrode portion P1 of the third intermediate gate electrode GM3.

In some implementations, the insulating patterns 33 having upper surfaces located at substantially the same level may include a first insulating pattern 33a having a lower surface located at a relatively high level and a second insulating pattern 33b having a lower surface located at a relatively low level, and the second vertical support structures SP2 having lower surfaces located at substantially the same level may include an upper vertical support structure SP2_U disposed below the first insulating pattern 33a and a lower vertical support structure SP2_L disposed below the second insulating pattern 33b.

The height level difference between the lower end of the first insulating pattern 33a and the upper end of the upper vertical support structure SP2_U may be different from the height level difference between the lower end of the second insulating pattern 33b and the upper end of the lower vertical support structure SP2_L.

The height level difference between the lower end of the first insulating pattern 33a and the upper end of the upper vertical support structure SP2_U may be smaller than the height level difference between the lower end of the second insulating pattern 33b and the upper end of the lower vertical support structure SP2_L. The lower chip structure LC may further include a source structure 80 and a lower insulating layer 83 disposed below the lowest interlayer insulating layer 8L among the interlayer insulating layers 8.

The source structure 80 may be disposed in the first and second memory cell array areas MA1 and MA2. The source structure 80 may include a silicon layer in contact with the channel layer 45. The source structure 80 may include a silicon layer having an N-type conductivity type. Accordingly, the source structure 80 may contact the vertical memory structures CH and the vertical dummy memory structures CHd.

The lower insulating layer 83 may be disposed in the connection area CA. The lower insulating layer 83 may be in contact with the vertical support structures SP.

The lower chip structure LC may further include a base 86 below the source structure 80 and the lower insulating layer 83. The base 86 may be a passivation layer.

The lower chip structure LC may further include a first upper insulating layer 36 and a second upper insulating layer 60 that are sequentially stacked. The first upper insulating layer 36 may be disposed on the uppermost interlayer insulating layer among the interlayer insulating layers 8, the capping insulating layer 12, the insulating patterns 33, the insulating spacers 27, and the plug portions P2.

The lower chip structure LC may further include separation structures MS. Each of the separation structures MS may have a line shape extending in the X-direction.

The separation structures MS may include a first separation structure MS1 and a second separation structure MS2 adjacent to each other in the Y-direction perpendicular to the X-direction.

In some implementations, the X-direction may be referred to as a first horizontal direction, and the Y-direction may be referred to as a second horizontal direction.

The plurality of gate electrodes GE, the insulating patterns 33, and the insulating spacers 27 may be disposed between the separation structures MS.

The plurality of gate electrodes GE, the insulating patterns 33, and the insulating spacers 27 may have a mirror symmetrical structure with respect to the first separation structure MS1.

Each of the insulating patterns 33 may contact one of the separation structures MS, and the insulating spacers 27 may be disposed on sides of the insulating patterns 33 that do not contact the separation structures MS.

In the top view, each of the plug portions P2b may include a bar-shaped first portion P2ba extending in the Y-direction, and a second portion P2bb bent from the first portion P2ba and extending in the X-direction.

In each of the plug portions P2b, the first portion P2ba may be adjacent to one of the separation structures MS adjacent to each other in the Y-direction, and the second portion (P2bb may be spaced apart from the separation structures MS.

The lower chip structure LC may further include bit line structures 63b electrically connected to the vertical memory structures CH, upper gate interconnection structures 63g1 electrically connected to the upper gate electrodes GU, intermediate gate interconnection structures 63g2 electrically connected to the intermediate gate electrodes GM, and lower gate interconnection structures 63g3 electrically connected to the lower gate electrodes GL.

Each of the bit line structures 63b may include a plug 65b connected to the pad layer 51 and a bit line 67b on the plug 65b. Each of the bit lines 67b may have a line shape extending in the Y-direction.

The upper gate interconnection structures 63g1 may include plugs 65g1 electrically connected to the upper gate electrodes GU, and interconnection lines 67g1 on the plugs 65g1.

The intermediate gate interconnection structures 63g2 may include plugs 65g2 electrically connected to the plug portions P2b of the intermediate gate electrodes GM, and interconnection lines 67g2 on the plugs 65g2.

The lower gate interconnection structures 63g3 may include plugs 65g3 connected to the plug portions P2b of the lower gate electrodes GL, and interconnection lines (interconnections) 67g3 on the plugs 65g3.

The lower chip structure LC may further include a lower insulating structure 69 (shown in FIG. 5) covering the bit line structures 63b, the upper gate interconnection structures 63g1, the intermediate gate interconnection structures 63g2 and the lower gate interconnection structures 63g3, and the lower interconnection structure 72 embedded within the lower insulating structure 69. The lower interconnection structure 72 may be electrically connected to the bit line structures 63b, the upper gate interconnection structures 63g1, the intermediate gate interconnection structures 63g2, and the lower gate interconnection structures 63g3. The lower interconnection structure 72 may include lower bonding pads 72C having an upper surface coplanar with the upper surface of the lower insulating structure 69.

Referring to FIG. 6, the lower chip structure LC may further include outer insulating layers 7 disposed outside the first and second memory cell array areas MA1 and MA2 and the connection area CA and alternately stacked with the interlayer insulating layers 8. The outer insulating layers 7 may be disposed on the same level as the plurality of gate electrodes GE. The outer insulating layers 7 may be formed of a material different from the interlayer insulating layers 8. For example, the insulating layers 7 may be formed of silicon nitride, and the interlayer insulating layers 8 may be formed of silicon oxide.

The lower chip structure LC may further include an input/output contact plug MCa penetrating through the outer insulating layers 7 and the interlayer insulating layers 8, and a source contact plug MCb that penetrates through the outer insulating layers 7 and the interlayer insulating layers 8 and is electrically connected to the source structure 80, outside the first and second memory cell array areas MA1 and MA2 and the connection area CA.

Each of the input/output contact plug MCa and the source contact plug MCb may include a plug portion PL integrally formed and a barrier layer (BM) covering side and lower surfaces of the plug portion PL.

The lower chip structure LC may further include an input/output connection interconnection 68b on the input/output contact plug MCa and a source connection interconnection 68a on the source contact plug MCb.

The lower chip structure LC may further include a conductive pattern 82 below the input/output contact plug MCa and an input/output pad IOP below the conductive pattern 82.

The upper chip structure UC may include a substrate 103, peripheral active regions 106a below the substrate 103, and a peripheral isolation region 106s defining the peripheral active regions 106a below the substrate 103. The substrate 103 may be a semiconductor substrate.

The upper chip structure UC may further include a peripheral circuit (PTR) under the substrate 103, an upper interconnection structure 112, and an upper insulating structure 110. The peripheral circuit PTR may include peripheral transistors including peripheral source/drain regions PSD spaced apart from each other within the peripheral active region 106a, a peripheral gate dielectric layer PGO below the peripheral active region 106a, and a peripheral gate electrode PGE below the peripheral gate dielectric layer PGO.

The upper chip structure UC may also be referred to as a peripheral circuit area.

The upper interconnection structure 112 may be buried within the upper insulating structure 220 and may be electrically connected to the peripheral transistors PTR. The upper interconnection structure 112 may include upper bonding pads 112C having a lower surface coplanar with the lower surface of the upper insulating structure 110. The lower bonding pads 72C and the upper bonding pads 112C may be bonded to each other by an inter-metal bonding process.

The plurality of gate electrodes GE and the vertical memory structures CH may be electrically connected to the peripheral circuit PTR through the lower interconnection structure 72 and the upper interconnection structure 112.

The plurality of gate electrodes GE and the vertical memory structures CH may be vertically overlapped with the peripheral circuit PTR.

Hereinafter, various modifications of the above-described examples that can, in some cases, increase the degree of integration and improve reliability of the semiconductor device 1 will be described. Various modifications of the components of the above-described examples described below will be described focusing on modified components, replaced components, or added components. In addition, the components that may be modified or replaced below are described with reference to the drawings below, and the components that may be modified or replaced may be combined with each other or with the components described above, thereby configuring various implementations of semiconductor devices within the scope of this disclosure. It will be understood that the various modifications discussed below are not mutually exclusive but, rather, can be combined together into the same implementation in any combination, unless indicated otherwise.

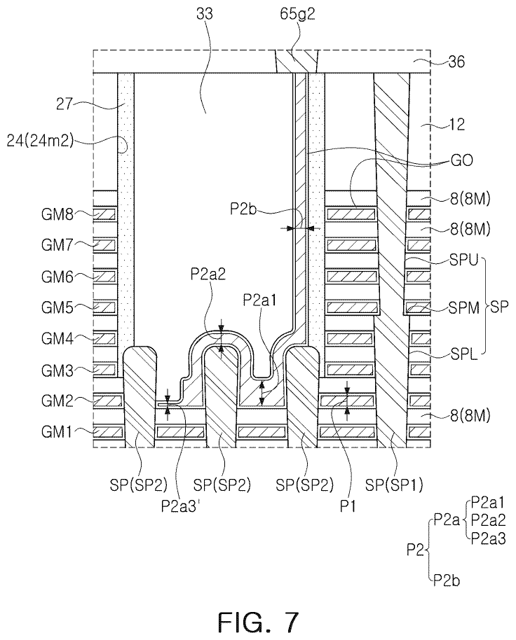

FIG. 7 is a diagram illustrating components modified from the partially enlarged view of FIG. 4B to illustrate a modified example of a semiconductor device according to some implementations.

Referring to FIG. 7, the third thickness portion (P2a3 in FIGS. 4B and 4C) in FIGS. 4B and 4C may be transformed into a third thickness portion (2a3′ with a reduced thickness. The thickness of the third thickness portion P2a3′ may be smaller than the thickness of the electrode portion P1. The thickness of the third thickness portion P2a3′ may be smaller than the thickness of the plug portion P2b. The thickness of the third thickness portion P2a3′ may be different from the thickness of the second thickness portion P2a2. The thickness of the third thickness portion P2a3′ may be smaller than the second thickness portion P2a2.

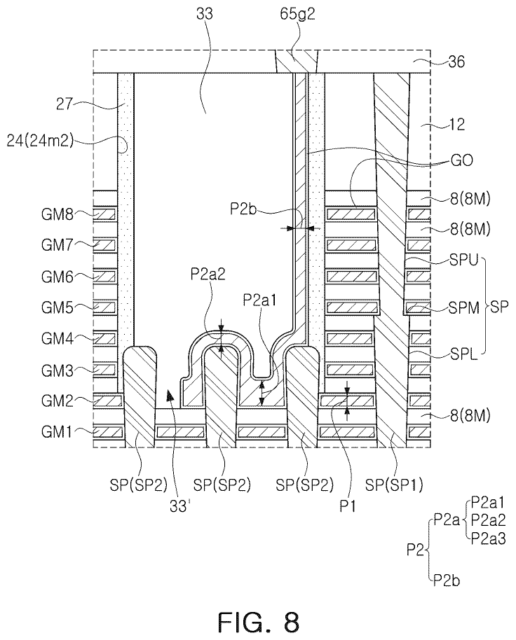

FIG. 8 is a diagram illustrating components modified from the partially enlarged view of FIG. 4B to illustrate a modified example of a semiconductor device according to some implementations.

Referring to FIG. 8, the insulating pattern 33 in FIGS. 4B and 4C may further include a protruding portion 33′ penetrating a portion of the lower portion P2a of the extension portion P2. Accordingly, the third thickness portion (P2a3 in FIGS. 4B and 4C) in FIGS. 4B and 4C may be omitted. For example, the lower portion P2a of the extension portion P2 may include the first thickness portion P2al and the second thickness portion (P2a2) as illustrated in FIGS. 4B and 4C, and the protruding portion 33′ of the insulating pattern 33 may have a lower surface at a level equal to or at a lower level than the lower surface of the second thickness portion P2a2.

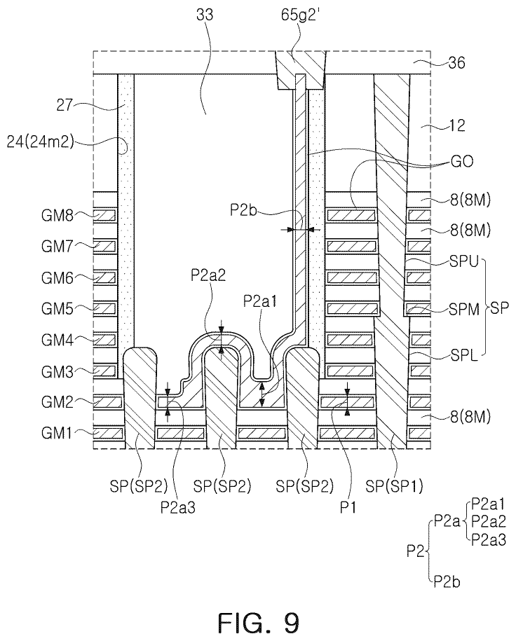

FIG. 9 is a diagram illustrating components modified from the partially enlarged view of FIG. 4B to illustrate a modified example of a semiconductor device according to some implementations.

Referring to FIG. 9, the plug (65g2 in FIGS. 4B and 4C) in contact with the upper surface of the plug portion P2b in FIGS. 4B and 4C may be transformed into a plug 65g2′ that contacts the upper surface and upper side of the plug portion P2b.

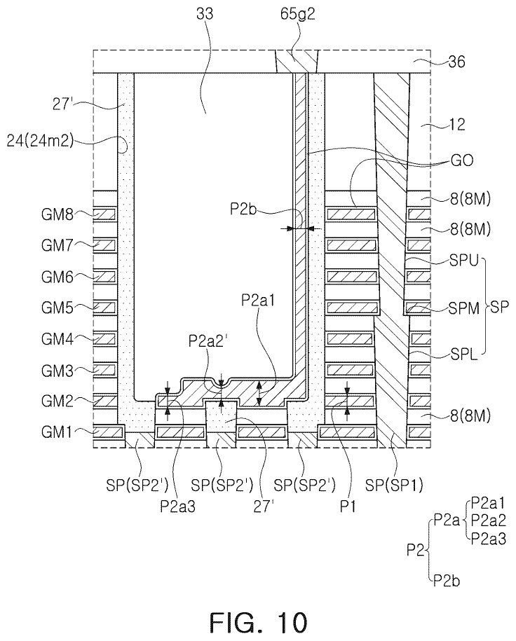

FIG. 10 is a diagram illustrating components modified from the partially enlarged view of FIG. 4B to illustrate a modified example of a semiconductor device according to some implementations.

Referring to FIG. 10, the upper surfaces of the second vertical support structures SP2 in FIGS. 4B and 4C may be transformed into second vertical support structures SP2′ disposed at a lower level than the lower surface of the electrode portion P1. The insulating spacers 27 in FIGS. 4B and 4C may be transformed into insulating spacers 27′ in contact with the upper surfaces of the second vertical support structures SP2′.

The second thickness portion P2a2 in FIGS. 4B and 4C may be transformed into a second thickness portion P2a2′ with a reduced thickness. The second thickness portion P2a2′ may have a concave upper surface. The thickness of the second thickness portion P2a2′ may be smaller than the thickness of the first thickness portion P2al. The upper surface of the second thickness portion P2a2′ may be disposed at a lower level than the upper surface of the first thickness portion P2a1.

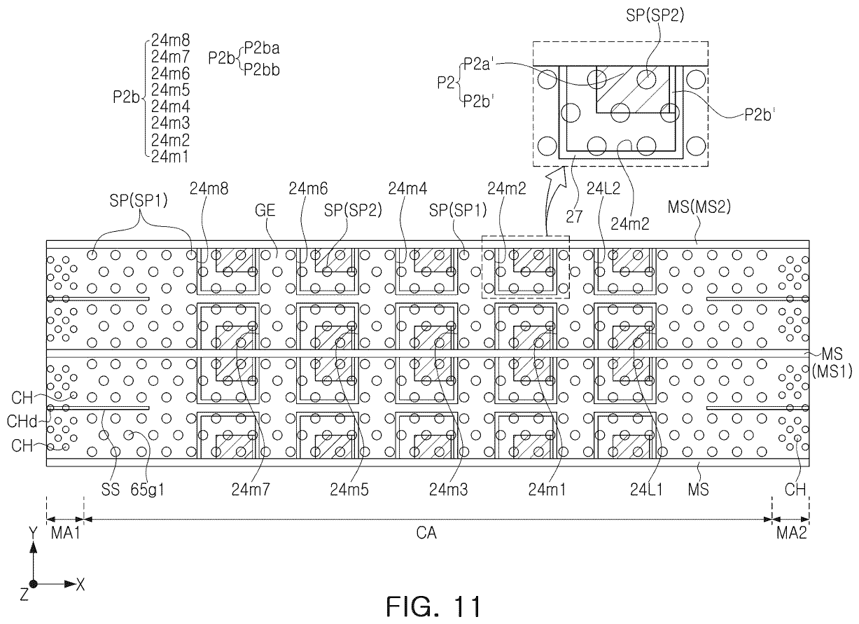

FIG. 11 is a diagram illustrating components modified from the top view of FIG. 1 to illustrate a modified example of a semiconductor device according to some implementations.

Referring to FIG. 11, in a top view, the plug portions P2b described above may be transformed into bar-shaped plug portions P2b′ extending in the Y-direction. In the top view, the lower portions P2a described above may be transformed into lower portions P2a′ spaced apart from the insulating spacers 27.

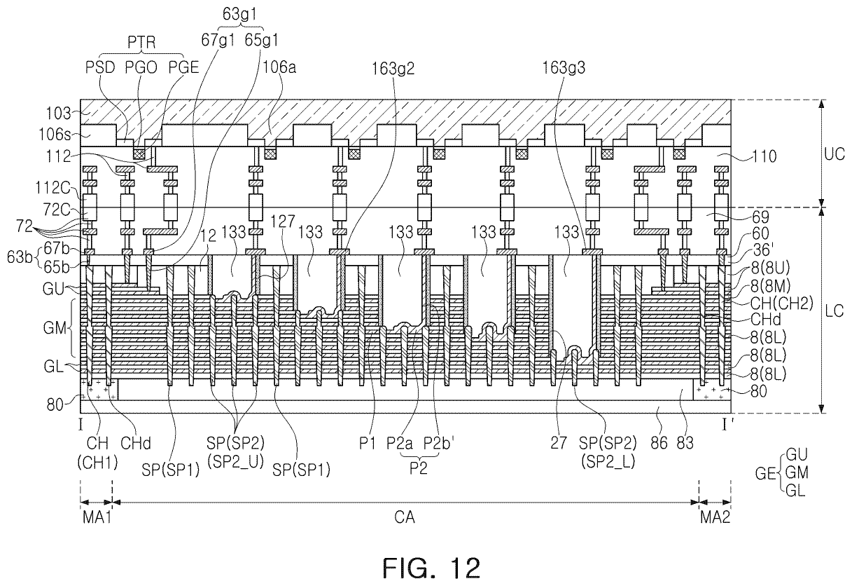

FIG. 12 is a diagram illustrating components modified from the cross-sectional view of FIG. 3 to illustrate a modified example of a semiconductor device according to some implementations.

Referring to FIG. 12, the insulating patterns 33, the insulating spacers 27, and the plug portions P2b described above may be replaced with insulating patterns 133, insulating spacers 127 and plug portions P2b′ having upper surfaces located on a level higher than that of the upper surfaces of the vertical memory structures CH and the vertical support structures SP, respectively. The insulating patterns 133, the insulating spacers 127, and the plug portions P2b′ may penetrate through an upper insulating layer 36′ disposed on a level higher than that of the upper surfaces of the vertical memory structures CH and the vertical support structures SP. The intermediate gate interconnection structures 63g2 and the lower gate interconnection structures 63g3 described above may be transformed into intermediate gate interconnection structures 163g2 in which the plugs 65g1 are omitted, and lower gate interconnection structures 163g3.

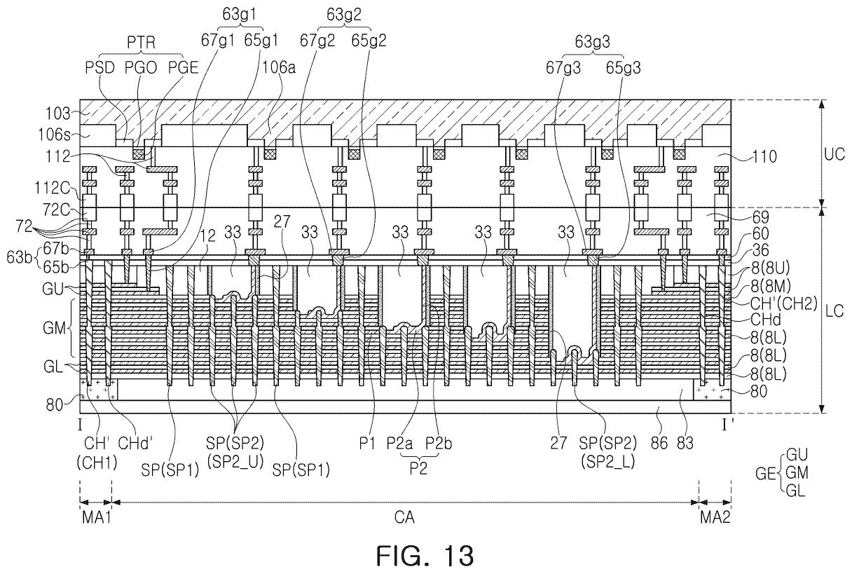

FIG. 13 is a diagram illustrating components modified from the cross-sectional view of FIG. 3 to illustrate a modified example of a semiconductor device according to some implementations.

Referring to FIG. 13, the vertical memory structures CH described above may be transformed into vertical memory structures CH′ having upper surfaces disposed at a level higher than that of the upper surfaces of the first vertical support structures SP1. Accordingly, the upper surfaces of the vertical memory structures CH′ may be disposed on a level higher than that of the upper surfaces of the insulating patterns 33, the insulating spacers 27, and the plug portions P2b.

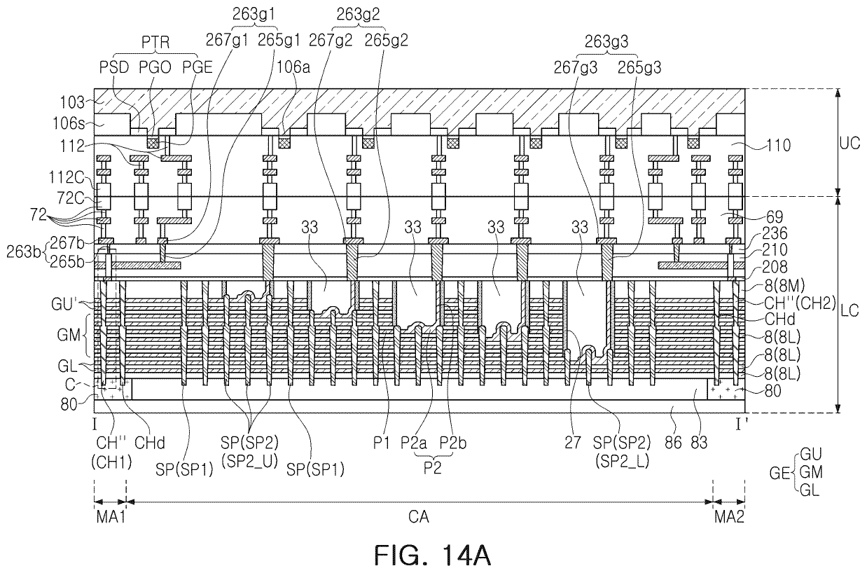

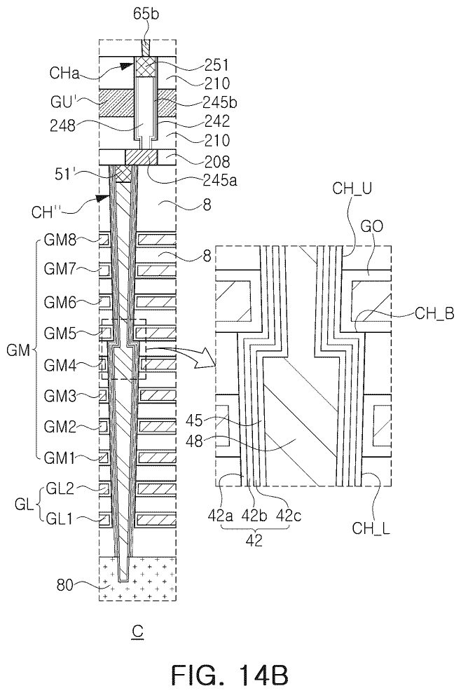

In FIGS. 14A and 14B, FIG. 14A is a diagram illustrating components modified from the cross-sectional view of FIG. 3 to illustrate a modified example of a semiconductor device according to some implementations, and FIG. 14B is a partial enlarged view illustrating the area marked ‘C’ in FIG. 14a.

Referring to FIGS. 14A and 14B, the one or a plurality of upper gate electrodes GU described above may be transformed into an upper gate electrode GU′ of increased thickness.

The thickness of the upper gate electrode GU′ may be greater than the thickness of each of the lower and intermediate gate electrodes GL and GM. The upper gate electrode GU′ may include the same material as that of the lower and intermediate gate electrodes GL and GM, but implementations are not limited thereto. For example, the upper gate electrode GU′ may include a material different from that of the lower and intermediate gate electrodes GL and GM.

The vertical memory structures (CH in FIG. 4A) described above may be transformed into vertical memory structures CH″ having an upper surface located at a lower level than the upper gate electrode GU′. The vertical memory structures CH″ may have a cross-sectional structure that is substantially the same as the vertical memory structures (CH in FIG. 4A) described above. The vertical memory structures CH″ may include material layers of the vertical memory structures (CH in FIG. 4A) described above.

The lower chip structure LC may further include a buffer insulating layer 208 on the vertical memory structures CH″, the insulating patterns 33, and the insulating spacers 27, a first upper insulating layer 210 on the buffer insulating layer 208, and a second upper insulating layer 236 on the first upper insulating layer 210.

The lower chip structure LC may further include a connection channel layer 245a penetrating through the buffer insulating layer 208 and connected to the pad layer 51′ of the channel structure CH″, and an upper channel structure CHa penetrating through the upper gate electrode GU′ and connected to the connection channel layer 245a.

The upper channel structure CHa may include an insulating core region 248, an upper channel layer 245b disposed on a side of the insulating core region 248 and connected to the connection channel layer 245a, an upper gate dielectric layer 242 disposed outside the upper channel layer 245b, and an upper pad layer 251 disposed on the insulating core region 248 and connected to the upper channel layer 245b.

The upper channel structure CHa and the upper gate electrode GU′ may be buried in the first upper insulating layer 210.

The lower chip structure LC may further include bit line structures 63b electrically connected to the vertical memory structures CH, upper gate interconnection structures 63g1 electrically connected to the upper gate electrodes GU, intermediate gate interconnection structures 63g2 electrically connected to the intermediate gate electrodes GM, and lower gate interconnection structures 63g3 electrically connected to the lower gate electrodes GL.

The bit line structure 63b described above may be transformed into bit line structures 263b each including a plug 265b connected to the upper pad layer 251 and a bit line 267b on the plug 265b.

The upper gate interconnection structure 63g1 described above may be transformed into an upper gate interconnection structure 263g1 including a plug 265g1 electrically connected to the upper gate electrode GU′, and interconnection lines 267g1 on the plug 265g1.

The intermediate gate interconnection structures 63g2 described above may be transformed into plugs 265g2 electrically connected to the plug portions P2b of the intermediate gate electrodes GM, and intermediate gate interconnection structures 263g2 including interconnections 267g2 on the plugs 265g2.

The lower gate interconnection structures 63g3 described above may be transformed into plugs 65g3 connected to the plug portions P2b of the lower gate electrodes GL, and lower gate interconnection structures 263g3 including interconnections 67g3 on the plugs 65g3.

The upper ends of the plug portions P2b may be disposed at a lower level than the upper gate electrode GU′.

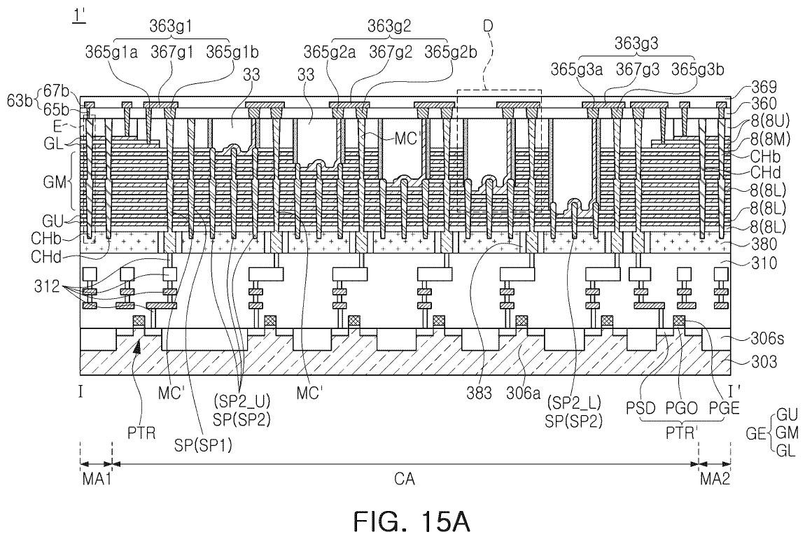

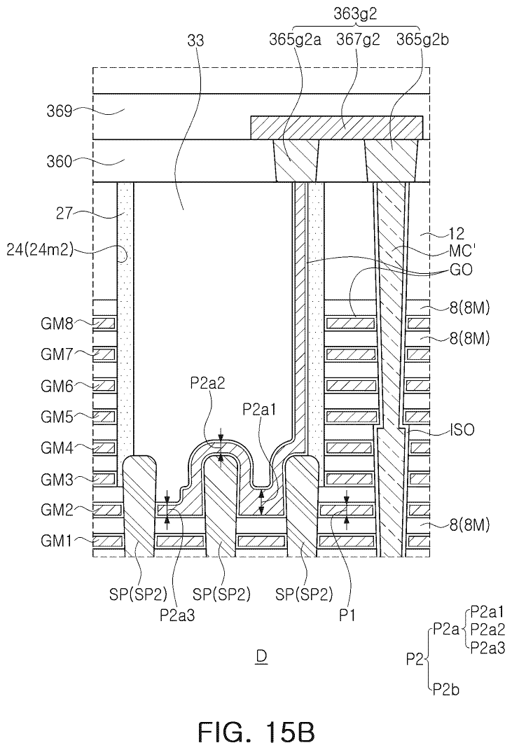

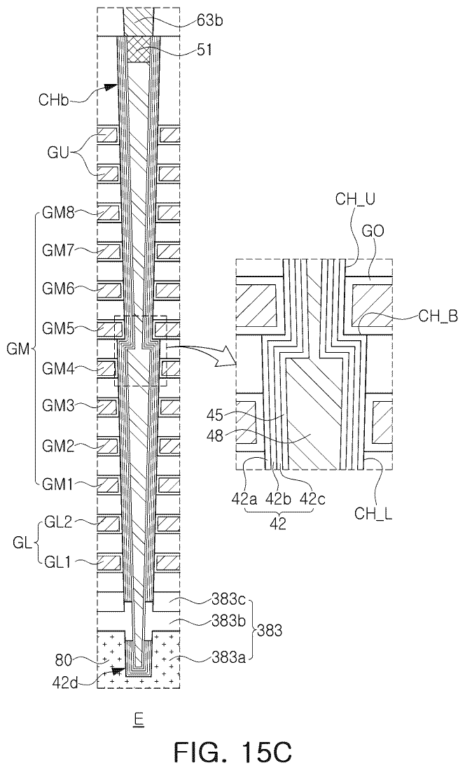

In FIGS. 15A, 15B and 15C, FIG. 15A is a diagram illustrating components modified from the cross-sectional view of FIG. 3 to illustrate a modified example of a semiconductor device according to some implementations, FIG. 15B is a partially enlarged view illustrating the area marked ‘D’ in FIG. 15A, and FIG. 15C is a partially enlarged view illustrating the area marked ‘E’ in FIG. 15A.

Referring to FIGS. 15A, 15B, and 15C, the semiconductor device 1 described above may be transformed into a semiconductor device 1′ composed of one chip.

A semiconductor device (1′) may include a substrate 303, peripheral active regions 306a on the substrate 303, and peripheral isolation regions 306s defining the peripheral active regions 306a on the substrate 303. The substrate 303 may be a semiconductor substrate. The upper chip structure (UC) may further include a peripheral circuit PTR, an interconnection structure 312, and an insulating structure 310 on the substrate 303.

The peripheral circuit PTR may include peripheral transistors including peripheral source/drain regions PSD spaced apart from each other within the peripheral active region 306a, a peripheral gate dielectric layer PGO on the peripheral active region 306a, and a peripheral gate electrode PGE on the peripheral gate dielectric layer PGO. The interconnection structure 312 may be buried within the insulating structure 310 and may be electrically connected to the peripheral transistors PTR.

The semiconductor device 1 ‘may further include a source structure 380 disposed on the insulating structure 310 and an insulating layer 383 penetrating through the source structure 380.

The semiconductor device 1’ may further include the plurality of gate electrodes GL, GM and GU, the interlayer insulating layers 8, the insulating patterns 33, the insulating spacers 27, the vertical memory structures CH, the vertical dummy memory structures CHd, the separation structures (MS in FIG. 1), and the vertical support structures SP. The plurality of gate electrodes GL, GM and GU and the interlayer insulating layers 8 may be disposed on the source structure 380 and the insulating layer 383.

The vertical memory structures CH and the vertical dummy memory structures CHd may contact the source structure 380. The vertical support structures SP may contact the source structure 380.

The source structure 380 may include a first conductive layer 383a, a second conductive layer 383b on the first conductive layer 383a, and a third conductive layer 383c on the second conductive layer 383b.

In the vertical memory structures CH described above, the data storage structure 42 may extend to cover the lower surface of the insulating core region 48, and the second conductive layer 383b may penetrate through the data storage structure 42 and contact the channel layer 45. The data storage structure 42 is separated by the second conductive layer 383b and may include a dummy portion 42d in contact with the first conductive layer 383a. Accordingly, the vertical memory structure CH described above may be transformed into a vertical memory structure CHb including a channel layer 45 in contact with the second conductive layer 383b.

At least one of the first conductive layer 383a, the second conductive layer 383b, and the third conductive layer 383c may include a silicon layer having an N-type conductivity type.

The semiconductor device 1′ may further include through-electrodes MC′ penetrating through the electrode portions P1 of the lower and intermediate gate electrodes GL, GM, and insulating side spacers ISO surrounding the sides of the through-electrodes MC′.

The semiconductor device 1′ may further include a first upper insulating layer 360 disposed on the plurality of gate electrodes GL, GM and GU, the interlayer insulating layers 8, the capping insulating layer 12, the insulating patterns 33, and the insulating spacers 27.

The semiconductor device 1′ may further include bit line structures 63b electrically connected to the vertical memory structures CH, upper gate interconnection structures 363g1 electrically connected to the upper gate electrodes GU, intermediate gate interconnection structures 363g2 electrically connected to the intermediate gate electrodes GM, and lower gate interconnection structures 363g3 electrically connected to the lower gate electrodes GL.

Each of the bit line structures 63b may include a plug 65b connected to the pad layer 51 and a bit line 67b on the plug 65b.

The upper gate interconnection structures 363g1 may include plugs 365g1a electrically connected to the upper gate electrodes GU, plugs 365g1b electrically connected to the through-electrodes MC′, and interconnection lines 367g1 on the plugs 365g1a, 365g2.

The intermediate gate interconnection structures 363g2 may include plugs 365g2a electrically connected to the plug portions P2b of the intermediate gate electrodes GM, plugs 365g2b electrically connected to the through-electrodes MC, and interconnection lines 367g2 on the plugs 365g2a, 365g2b.

The lower gate interconnection structures 363g3 may include plugs 365g3a connected to the plug portions P2b of the lower gate electrodes GL, plugs 365g3b electrically connected to the through-electrodes MC, and interconnection lines 367g3 on the plugs 365g3a and 365g3b.

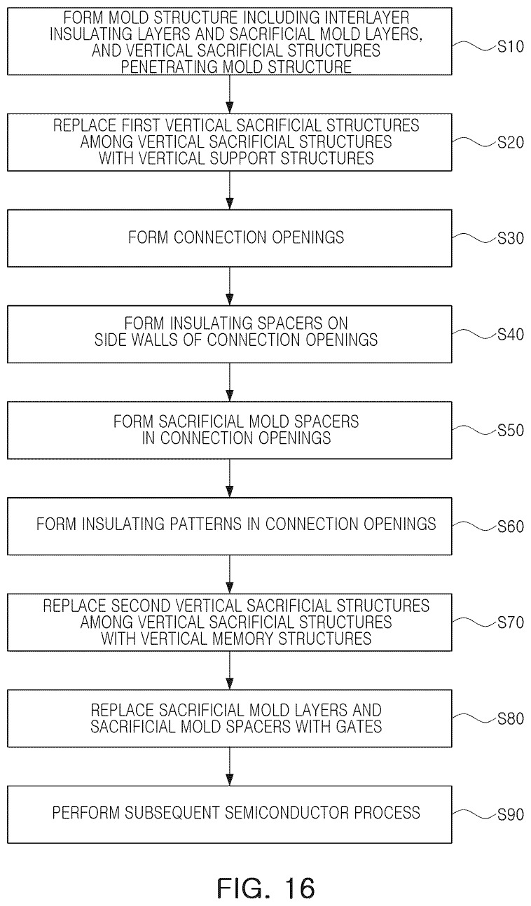

Next, an illustrative example of a semiconductor device manufacturing method according to some implementations will be described. FIG. 16 is a process flow chart illustrating an example of a semiconductor device manufacturing method according to an some implementations.

Referring to FIG. 16, an operation (S10) of forming a mold structure including interlayer insulating layers 8 and sacrificial mold layers, and vertical sacrificial structures penetrating through the mold structure may be performed. An operation (S20) of replacing the first vertical sacrificial structures among the vertical sacrificial structures with vertical support structures SP may be performed. An operation (S30) of forming the connection openings 24 may be performed. A step S40 of forming insulating spacers 27 on the side walls of the connection openings 24 may be performed. An operation (S50) of forming sacrificial mold spacers in the connection openings 24 may be performed. A step S60 of forming insulating patterns 33 in the connection openings 24 may be performed. An operation (S70) of replacing second vertical sacrificial structures among the vertical sacrificial structures with vertical memory structures CH may be performed. An operation (S80) of replacing the sacrificial mold layers and sacrificial mold spacers with gates GE may be performed. Subsequently, subsequent semiconductor manufacturing processes may be performed (S90).

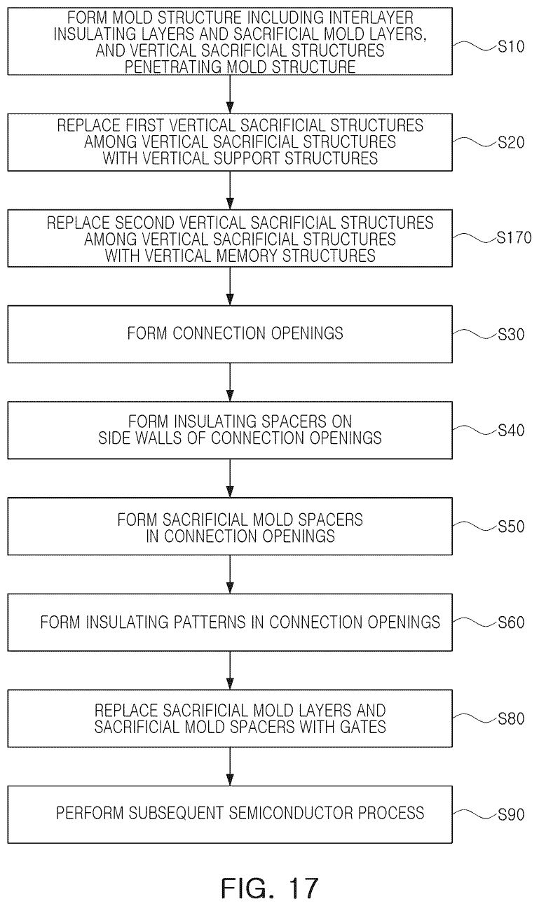

FIG. 17 is a process flow diagram illustrating another example of a semiconductor device manufacturing method according to some implementations.

Referring to FIG. 17, the operation (S70) of replacing the second vertical sacrificial structures among the vertical sacrificial structures described in FIG. 16 with vertical memory structures CH may be performed before the operation (S30) of forming the connection openings 24. Accordingly, after performing the step S170 of replacing the second vertical sacrificial structures among the vertical sacrificial structures with the vertical memory structures CH, the step S30 of forming the connection openings 24 may be performed.

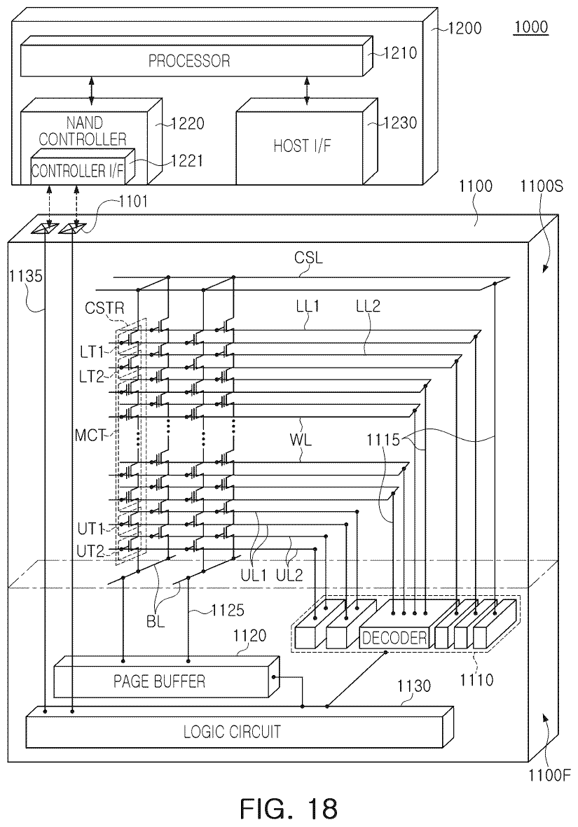

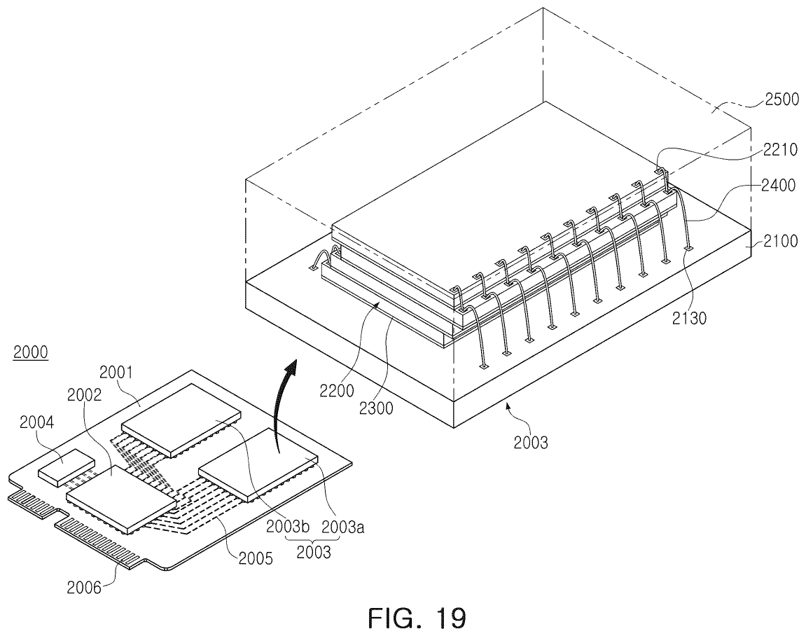

Next, a data storage system including a semiconductor device according to some implementations will be described with reference to FIGS. 18 and 19, respectively.

FIG. 18 is a diagram schematically illustrating a data storage system including a semiconductor device according to some implementations.

Referring to FIG. 18, a data storage system 1000 according to some implementations may include a semiconductor device 1100, and a controller 1200 that is electrically connected to the semiconductor device 1100 and controls the semiconductor device 1100. The data storage system 1000 may be a storage device including a semiconductor device 1100 or an electronic device including a storage device. For example, the data storage system 1000 may be a solid state drive device (SSD) device, a universal serial bus (USB) device, a computing system, a medical device, or a communication device including the semiconductor device 1100.

In some implementations, the data storage system 1000 may be an electronic system that stores data.

The semiconductor device 1100 may be a non-volatile memory device. For example, the semiconductor device 1100 may be a semiconductor device according to any one of the examples described above with reference to FIGS. 1 to 15C. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure PERI described above. The peripheral circuit (PTR in FIG. 3) described above may be a transistor that may configure the decoder circuit 1110, page buffer 1120, and logic circuit 1130.

The second structure (1100S) may be a memory structure including bit lines (BL), common sources (CSL), word lines (WL), first and second gate upper lines (UL1, UL2), first and second gate lower lines (LL1, LL2), and memory cell strings (CSTR) between the bit line (BL) and the common source line (CSL).

In the second structure 1100S, each memory cell string (CSTR) may include lower transistors (LT1, LT2) adjacent to the common source (CSL), upper transistors (UT1, UT2) adjacent to the bit line (BL), and a plurality of memory cell transistors (MCT) disposed between the lower transistors (LT1, LT2) and the upper transistors (UT1, UT2). The number of lower transistors LT1 and LT2 and the number of upper transistors UT1 and UT2 may vary depending on the implementation.

The plurality of memory cell transistors (MCTs) may include the intermediate gate electrodes (GM), which may be the word lines described above, the channel layer 45, and the data storage structure 42.

In some implementations, the upper transistors UT1 and UT2 may include string select transistors, and the lower transistors LT1 and LT2 may include ground selection transistors. The gate lower lines LL1 and LL2 may be gate electrodes of the lower transistors LT1 and LT2, respectively. The word lines (WL) may be gate electrodes of memory cell transistors (MCT), and the gate upper lines UL1 and UL2 may be gate electrodes of the upper transistors UT1 and UT2, respectively.

The lower gate electrodes GL described above may be the lower gate lines LL1 and LL2, the intermediate gate electrodes (GM) may be word lines (WL), and the upper gate electrodes GU may form the upper gate lines UL1 and UL2.

The common source (CSL), the first and second gate lower lines (LL1, LL2), the word lines (WL), and the first and second gate upper lines (UL1, UL2) may be electrically connected to the decoder circuit 1110 through first connection interconnections 1115 extending from the first structure 1100F to the second structure 1100S.

The bit lines BL may be electrically connected to the page buffer 1120 through second connection interconnections 1125 extending from the first structure 1100F to the second structure 1100S.

In the first structure 1100F, the decoder circuit 1110 and the page buffer 1120 may execute a control operation on at least one selected memory cell transistor (MCT) among the plurality of memory cell transistors (MCT). The decoder circuit 1110 and the page buffer 1120 may be controlled by a logic circuit 1130.

The semiconductor device 1100 may further include an input/output pad 1101. The semiconductor device 1100 may communicate with the controller 1200 through the input/output pad 1101 that is electrically connected to the logic circuit 1130. The input/output pad 1101 may be electrically connected to the logic circuit 1130 through an input/output connection interconnection 1135 extending from the first structure 1100F to the second structure 1100S. Therefore, the controller 1200 is electrically connected to the semiconductor device 1100 through the input/output pad 1101, and the semiconductor device 1100 may be controlled.

The input/output pad 1101 may be the input/output pad (IOP) described above.

The controller 1200 may include a processor 1210, a NAND controller 1220, and a host interface 1230. In some implementations, the data storage system 1000 may include a plurality of semiconductor devices 1100, and in this case, the controller 1200 may control the plurality of semiconductor devices 1100.

The processor 1210 may control the overall operation of the data storage system 1000, including the controller 1200. The processor 1210 may operate according to predetermined firmware and may control the NAND controller 1220 to access the semiconductor device 1100. The NAND controller 1220 may include a NAND interface 1221 that processes communication with the semiconductor device 1100. Through the NAND interface 1221, a control command for controlling the semiconductor device 1100, data to be written to the memory cell transistors (MCT) of the semiconductor device 1100, and Data to be read from the memory cell transistors (MCT) may be transmitted. The host interface 1230 may provide a communication function between the data storage system 1000 and an external host. When a control command is received from an external host through the host interface 1230, the processor 1210 may control the semiconductor device 1100 in response to the control command.

FIG. 19 is a perspective view schematically illustrating a data storage system including a semiconductor device according to some implementations.

Referring to FIG. 19, a data storage system 2000 according to some implementations includes a main board 2001, a controller 2002 mounted on the main board 2001, one or more semiconductor packages 2003, and a DRAM 2004. The semiconductor package 2003 and the DRAM 2004 may be connected to the controller 2002 through interconnection patterns 2005 formed on the main board 2001.

The main board 2001 may include a connector 2006 including a plurality of pins coupled to an external host. The number and arrangement of the plurality of pins in the connector 2006 may vary depending on the communication interface between the data storage system 2000 and the external host. In some implementations, the data storage system 2000 may communicate with an external host through any one of the following interfaces: Universal Serial Bus (USB), Peripheral Component Interconnect Express (PCI-Express), Serial Advanced Technology Attachment (SATA), and M-Phy for Universal Flash Storage (UFS). In some implementations, the data storage system 2000 may operate with power supplied from an external host through the connector 2006. The data storage system 2000 may further include a Power Management Integrated Circuit (PMIC) that distributes power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory to alleviate the speed difference between the semiconductor package 2003, which is a data storage space, and an external host. The DRAM 2004 included in the data storage system 2000 may also operate as a type of cache memory, and in a control operation for the semiconductor package 2003, a space for temporarily storing data may be provided. When the data storage system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b that are spaced apart from each other. The first and second semiconductor packages 2003a and 2003b may each include a plurality of semiconductor chips 2200. Each of the semiconductor chips 2200 may include a semiconductor device according to any one of the examples described above with reference to FIGS. 1 to 15C.

Each of the first and second semiconductor packages 2003a and 2003b may include a package substrate 2100, semiconductor chips 2200 on a package substrate 2100, adhesive layers 2300 disposed on the lower surface of each of the semiconductor chips 2200, a connection structure 2400 that electrically connects the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each of the semiconductor chips 2200 may include an input/output pad 2210.

In some implementations, the connection structure 2400 may be a bonding wire that electrically connects the input/output pad 2210 and the upper package pads 2130. Accordingly, in each of the first and second semiconductor packages 2003a and 2003b, the semiconductor chips 2200 may be electrically connected to each other using a bonding wire method and may be electrically connected to the upper package pads 2130 of the package substrate 2100. According to some implementations, in each of the first and second semiconductor packages 2003a and 2003b, the semiconductor chips 2200 may be electrically connected to each other by a connection structure including a through-electrode (Through Silicon Via, TSV), instead of the bonding wire-type connection structure 2400.

In some implementations, the controller 2002 and the semiconductor chips 2200 may be included in one package. For example, the controller 2002 and the semiconductor chips 2200 are mounted on a separate interposer board different from the main board 2001, and the controller 2002 and the semiconductor chips 2200 may be connected to each other through an interconnection line formed on the interposer substrate. In the semiconductor package 2003, the package substrate 2100 may be a printed circuit board. Each of the semiconductor chips 2200 may include a semiconductor device according to any one of the examples described above with reference to FIGS. 1 to 15C.

As set forth above, according to some implementations, a semiconductor device including a word line including an electrode portion and an extension portion extending to the electrode portion, and a data storage system including the same, may be provided. The extension portion may include a lower portion extending from the electrode portion and a plug portion extending upwardly from at least one side of the lower portion, and the plug portion may be electrically connected to the gate connection interconnection structure. Accordingly, a word line including an electrode portion and an extension portion formed integrally may be provided without a separate contact plug, thereby improving the degree of integration of the semiconductor device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some examples have been illustrated and described above, it will be apparent to those skilled in the art that modifications and variations could be made without departing from the scope of the present inventive concept as defined by the appended claims.

What is claimed is:

1. A semiconductor device comprising:
a first word line having a first electrode portion and a first extension portion extending from the first electrode portion;
a second word line having a second electrode portion disposed at a higher level than the first electrode portion and a second extension portion extending from the second electrode portion;
a first vertical memory structure extending through the first electrode portion and the second electrode portion in a vertical direction; and
a first interconnection structure electrically connected to the first extension portion,
wherein the first extension portion includes:
a first lower portion extending from the first electrode portion, and
a first plug portion extending upwardly from at least one side of the first lower portion and connected to the first interconnection structure, and
wherein at least a portion of the first lower portion has a thickness greater than a thickness of the first electrode portion.

2. The semiconductor device of claim 1, wherein the first lower portion includes a first thickness portion and a second thickness portion having different thicknesses.

3. The semiconductor device of claim 2, wherein the first thickness portion has a thickness greater than a thickness of the second thickness portion, and
wherein at least a portion of the first plug portion has a thickness less than the thickness of the at least a portion of the first lower portion having the thickness greater than the thickness of the first electrode portion.

4. The semiconductor device of claim 3, wherein the thickness of the at least a portion of the first plug portion is substantially the same as the thickness of the second thickness portion.

5. The semiconductor device of claim 2, wherein the first lower portion further includes a third thickness portion, and
wherein a thickness of the third thickness portion is less than a thickness of the first electrode portion and is different from a thickness of the second thickness portion.

6. The semiconductor device of claim 1, further comprising:
a first vertical support structure extending through the first electrode portion and the second electrode portion in the vertical direction; and
a second vertical support structure disposed below the first lower portion of the first extension portion,
wherein an upper end of the second vertical support structure is at a higher level than an upper surface of the first electrode portion,
wherein the first lower portion includes:
a first thickness portion vertically non-overlapping with the second vertical support structure; and
a second thickness portion covering the upper end of the second vertical support structure, and
wherein the first thickness portion has a thickness greater than a thickness of the second thickness portion.

7. The semiconductor device of claim 1, further comprising:
a first vertical support structure extending through the first electrode portion and the second electrode portion in the vertical direction; and
a second vertical support structure disposed below the first lower portion of the first extension portion,
wherein the second vertical support structure has an upper surface disposed at a lower level than an upper surface of the first electrode portion.

8. The semiconductor device of claim 1, further comprising:
a first vertical support structure extending through the first electrode portion and the second electrode portion in the vertical direction; and
a second vertical support structure disposed below the first lower portion of the first extension portion,
wherein the first vertical memory structure includes:
an insulating core region;
a channel layer on a side surface of the insulating core region; and
a data storage structure on an outer side surface of the channel layer, and
wherein each of the first vertical support structure and the second vertical support structure includes an insulating material and does not include a material of the channel layer.

9. The semiconductor device of claim 1, further comprising:
a first insulating pattern on the first lower portion; and
a first insulating spacer on a side surface of the first insulating pattern,
wherein the first plug portion is disposed between the side surface of the first insulating pattern and the first insulating spacer.

10. The semiconductor device of claim 9, wherein the first insulating pattern includes a protrusion extending through the first lower portion.

11. A semiconductor device comprising:
a first memory cell array area and a connection area adjacent to the first memory cell array area;
separation structures crossing the first memory cell array area and the connection area;
word lines disposed between the separation structures and within the first memory cell array area and the connection area;
a first vertical memory structure within the first memory cell array area, wherein the first vertical memory structure extends through the word lines and includes a first data storage structure;
vertical support structures within the connection area; and
a first insulating pattern,
wherein the word lines include a first word line and a second word line,
wherein the first word line includes a first electrode portion and a first extension portion extending from the first electrode portion,
wherein the second word line includes:
a second electrode portion disposed at a higher level than the first electrode portion, and
a second extension portion extending from the second electrode portion,
wherein the first extension portion includes:
a first lower portion disposed below the first insulating pattern, and
a first plug portion extending from the first lower portion and disposed on a side surface of the first insulating pattern,
wherein an upper end of the first plug portion is at a higher level than an uppermost word line of the word lines,
wherein the first insulating pattern extends through the second electrode portion of the second word line,
wherein the vertical support structures include:
a first vertical support structure extending through the first electrode portion and the second electrode portion; and
a second vertical support structure disposed below the first insulating pattern, and
wherein the first lower portion includes:
a first thickness portion disposed below the first insulating pattern and vertically non-overlapping with the vertical support structures; and
a second thickness portion disposed between the second vertical support structure and the first insulating pattern.

12. The semiconductor device of claim 11, wherein the first thickness portion has a thickness greater than a thickness of each of the first electrode portion and the second electrode portion.

13. The semiconductor device of claim 11, wherein a lower surface of the first vertical support structure and a lower surface of the second vertical support structure are disposed at substantially the same level, and
wherein an upper surface of the first insulating pattern and an upper surface of the first vertical support structure are disposed at a higher level than the uppermost word line of the word lines.

14. The semiconductor device of claim 11, wherein, in a top view, each of the separation structures has a line shape extending in a first horizontal direction, and
wherein, in the top view, the first plug portion includes a first portion having a bar shape extending in a second horizontal direction perpendicular to the first horizontal direction.

15. The semiconductor device of claim 14, wherein, in the top view, the first plug portion further includes a second portion bent from the first portion and extending in the first horizontal direction,
wherein the first portion is adjacent to a first separation structure of the separation structures, and
wherein the second portion is spaced apart from the separation structures.

16. The semiconductor device of claim 11, further comprising:
a second memory cell array area; and
a second vertical memory structure including a second data storage structure,
wherein the connection area is disposed between the first memory cell array area and the second memory cell array area,
wherein the separation structures cross the connection area and the second memory cell array area,
wherein the word lines extend from within the connection area into the second memory cell array area, and
wherein the second vertical memory structure extends through the word lines in the second memory cell array area.

17. The semiconductor device of claim 11, further comprising a second insulating pattern,
wherein the second extension portion includes a second lower portion disposed below the second insulating pattern and a second plug portion extending from the second lower portion and disposed on a side surface of the second insulating pattern,
wherein an upper end of the second plug portion is disposed at substantially the same level as an upper end of the first plug portion,
wherein upper surfaces of the first insulating pattern and the second insulating pattern are at a higher level than the uppermost word line, and
wherein the second insulating pattern is at a higher level than the first electrode portion of the first word line.

18. The semiconductor device of claim 11, further comprising a peripheral circuit vertically overlapping the word lines.

19. A data storage system comprising:
a semiconductor device including an input/output pad; and
a controller electrically connected to the semiconductor device through the input/output pad and configured to control the semiconductor device,
wherein the semiconductor device includes:
a first word line having a first electrode portion and a first extension portion extending from the first electrode portion;
a second word line having a second electrode portion disposed at a higher level than the first electrode portion and a second extension portion extending from the second electrode portion;
a first vertical memory structure extending through the first electrode portion and the second electrode portion in a vertical direction; and
a first interconnection structure electrically connected to the first extension portion,
wherein the first extension portion includes a first lower portion extending from the first electrode portion and a first plug portion extending upwardly from at least one side of the first lower portion and connected to the first interconnection structure, and
wherein at least a portion of the first lower portion has a thickness greater than a thickness of the first electrode portion.

20. The data storage system of claim 19, wherein the semiconductor device further includes a first vertical support structure extending through the first electrode portion and the second electrode portion in the vertical direction and a second vertical support structure disposed below the first lower portion of the first extension portion,
wherein an upper end of the second vertical support structure is at a higher level than an upper surface of the first electrode portion,
wherein the first lower portion includes:
a first thickness portion vertically non-overlapping with the second vertical support structure; and
a second thickness portion covering the upper end of the second vertical support structure, and
wherein the first thickness portion has a thickness greater than a thickness of the second thickness portion.
